(19) United States
(12) Patent Application Publication
(10) Pub. No.: US 2026/0314189 A1
(43) Pub. Date: Oct. 8, 2026

(54) LOW-REFLECTION FILM, DISPLAY SUBSTRATE AND MANUFACTURING METHOD THEREFOR, AND DISPLAY APPARATUS

(71) Applicants: Hefei BOE Ruisheng Technology Co., Ltd., Hefei, Anhui (CN); BOE TECHNOLOGY GROUP CO., LTD., Beijing (CN)

(72) Inventors: Haifeng HU, Beijing (CN); Ting ZENG, Beijing (CN); Fang LU, Beijing (CN); Tao XIAO, Beijing (CN); Xin ZHA, Beijing (CN); Xiaoxiao LIU, Beijing (CN); Renwei ZHANG, Beijing (CN)

(73) Assignees: Hefei BOE Ruisheng Technology Co., Ltd., Hefei, Anhui (CN); BOE TECHNOLOGY GROUP CO., LTD., Beijing (CN)

(21) Appl. No.: 19/482,254

(22) PCT Filed: Apr. 17, 2024
(86) PCT No.: PCT/CN2024/088430

§ 371 Date: Nov. 7, 2025

(30) Foreign Application Priority Data
May 29, 2023 (CN) 202310625409.1

(51) Int. Cl. H10K 59/126; H10K 59/12; H10K 59/131

(52) U.S. Cl. CPC H10K 59/126; H10K 59/1201; H10K 59/131

(57) ABSTRACT

Disclosed is an OLED double-sided display panel, comprising: a light-emitting unit (21); a control circuit (22), wherein the control circuit (22) is connected to the light-emitting unit (21) and is used for controlling the light-emitting unit (21) to emit light; light filter units (23, 24) arranged on at least one light emergent side of the light-emitting unit (21), wherein the light filter units (23, 24) are used for filtering out light, emitted from the top and the bottom of the light-emitting unit (21), of at least part of wavebands; and a transparent substrate (25) for bearing the light-emitting unit (21), the control circuit (22) and the light filter units (23, 24). The OLED double-sided display panel has a special light filter structure and can focus emitted light on a relatively narrow waveband, such that the problem of the reduction of color saturation caused by a completely transparent double-sided display panel is effectively solved, and the emitted light has relatively high color purity, thereby ensuring picture quality.

### CROSS-REFERENCE TO RELATED APPLICATIONS

This application is a national phase entry under 35 USC 371 of International Patent Application No. PCT/CN2024/088430, filed on Apr. 17, 2024, which claims priority to Chinese Patent Application No. 202310625409.1, filed on May 29, 2023, which are incorporated herein by reference in their entirety.

### TECHNICAL FIELD

The present disclosure relates to the field of display technologies, and in particular, to a low-reflection film, a display substrate and a manufacturing method therefor, and a display apparatus.

### BACKGROUND

Organic light-emitting diodes (OLEDs) have many advantages such as self-luminescence, high brightness, high contrast, fast response speed, wide viewing angle, simple structure, and flexible display. Mini light-emitting diodes (Mini LEDs) and micro light-emitting diodes (Micro LEDs) have excellent performances such as lower power consumption, faster response, longer lifetime, higher color saturation, and higher contrast.

### SUMMARY

In an aspect, a low-reflection film is provided. The low-reflection film includes a first metal layer, a first inorganic layer, a second metal layer, and a second inorganic layer. The first inorganic layer is located on a side of the first metal layer, and a refractive index of the first inorganic layer is less than a refractive index of the first metal layer. The second metal layer is located on a side of the first inorganic layer away from the first metal layer, and a refractive index of the second metal layer is greater than the refractive index of the first inorganic layer. The second inorganic layer is located on a side of the second metal layer away from the first inorganic layer, and a refractive index of the second inorganic layer is less than the refractive index of the second metal layer.

In some embodiments, in a direction perpendicular to the first metal layer, a dimension of the first metal layer is greater than a dimension of the first inorganic layer.

In some embodiments, in the direction perpendicular to the first metal layer, the dimension of the first metal layer is greater than a dimension of the second metal layer.

In some embodiments, in the direction perpendicular to the first metal layer, the dimension of the first metal layer is greater than a dimension of the second inorganic layer.

In some embodiments, in a direction perpendicular to the first metal layer, a ratio of a dimension of the first metal layer to a dimension of the first inorganic layer is greater than or equal to 2.5 and less than or equal to 3.5.

In some embodiments, in the direction perpendicular to the first metal layer, a ratio of the dimension of the first metal layer to a dimension of the second metal layer is greater than or equal to 11.5 and less than or equal to 17.5.

In some embodiments, in the direction perpendicular to the first metal layer, a ratio of the dimension of the first metal layer to a dimension of the second inorganic layer is greater than or equal to 2 and less than or equal to 3.

In some embodiments, in a direction perpendicular to the first metal layer, a dimension of the first inorganic layer is greater than a dimension of the second metal layer.

In some embodiments, in the direction perpendicular to the first metal layer, a dimension of the second inorganic layer is greater than the dimension of the second metal layer.

In some embodiments, in a direction perpendicular to the first metal layer, a ratio of a dimension of the first inorganic layer to a dimension of the second metal layer is greater than or equal to 4 and less than or equal to 6.5.

In some embodiments, in the direction perpendicular to the first metal layer, a ratio of a dimension of the second inorganic layer to the dimension of the second metal layer is greater than or equal to 4.5 and less than or equal to 7.

In some embodiments, in a direction perpendicular to the first metal layer, a dimension of the low-reflection film is greater than or equal to 1800 Å and less than or equal to 2500 Å.

In some embodiments, the low-reflection film includes N metal layers and a plurality of inorganic layers, and the N metal layers have refractive indexes greater than refractive indexes of the plurality of inorganic layers; and the N metal layers and the plurality of inorganic layers are alternately stacked in sequence, where N is a positive integer greater than or equal to three.

In another aspect, a display substrate is provided. The display substrate includes at least one display side. The display substrate further includes a base substrate, a plurality of metal wires, light-emitting units, and at least one low-reflection film as described in any one of the above embodiments. The base substrate is defined to have light-emitting regions and a non-light-emitting region other than the light-emitting regions. The plurality of metal wires are located on a side of the base substrate and disposed in the non-light-emitting region. The light-emitting units are located on a side of the plurality of metal wires away from the base substrate and disposed in the light-emitting regions. The at least one low-reflection film is located on at least one side of the plurality of metal wires close to the at least one display side and is disposed in the non-light-emitting region.

In some embodiments, the display substrate is a top-emission display substrate; and the low-reflection film is located on a side of the light-emitting units away from the base substrate.

In some embodiments, the display substrate is a bottom-emission display substrate; and the low-reflection film is located between the base substrate and the plurality of metal wires.

In some embodiments, the display substrate is a double-sided-emission display substrate. The at least one low-reflection film includes a first low-reflection film and/or a second low-reflection film. The first low-reflection film is located between the base substrate and the plurality of metal wires; and/or the second low-reflection film is located on a side of the light-emitting units away from the base substrate.

In yet another aspect, a manufacturing method for a display substrate is provided. The manufacturing method includes: forming a base substrate, where the base substrate is defined to have light-emitting regions and a non-light-emitting region other than the light-emitting regions; forming a plurality of metal wires on a side of the base substrate, the plurality of metal wires being disposed in the non-light-emitting region; and forming light-emitting units on a side of the plurality of metal wires away from the base substrate, the light-emitting units being disposed in the light-emitting regions.

The method further includes: after forming the light-emitting units, forming a low-reflection film on a side of the light-emitting units away from the base substrate; and/or before forming the light-emitting units, forming a low-reflection film on the side of the base substrate. The low-reflection film is disposed in the non-light-emitting region; the low-reflection film includes a first metal layer, a first inorganic layer, a second metal layer and a second inorganic layer. The first inorganic layer is located on a side of the first metal layer, and a refractive index of the first inorganic layer is less than a refractive index of the first metal layer. The second metal layer is located on a side of the first inorganic layer away from the first metal layer, and a refractive index of the second metal layer is greater than the refractive index of the first inorganic layer. The second inorganic layer is located on a side of the second metal layer away from the first inorganic layer, and a refractive index of the second inorganic layer is less than the refractive index of the second metal layer.

In some embodiments, forming the low-reflection film on the side of the light-emitting units away from the base substrate, includes: forming a first low-reflection base film by sequentially forming a whole-layer first metal layer, a whole-layer first inorganic layer, a whole-layer second metal layer, and a whole-layer second inorganic layer that are stacked on the side of the light-emitting units away from the base substrate; and removing a portion of the first low-reflection base film located in the light-emitting regions by using a dry etching process, where a portion of the first low-reflection base film located in the non-light-emitting region is retained as the low-reflection film.

In some embodiments, forming the low-reflection film on the side of the base substrate, includes: forming a second low-reflection base film by sequentially forming a whole-layer second inorganic layer, a whole-layer second metal layer, a whole-layer first inorganic layer, and a whole-layer first metal layer that are stacked on the side of the base substrate; and removing a portion of the second low-reflection base film located in the light-emitting regions by using a dry etching process, where a portion of the second low-reflection base film located in the non-light-emitting region is retained as the low-reflection film.

In yet another aspect, a display apparatus is provided. The display apparatus includes a circuit board and the display substrate as described in any one of the above embodiments. The display substrate is located on a side of the circuit board, and is coupled to the circuit board.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, and are not limitations on actual sizes of products, actual processes of methods and actual timings of signals involved in the embodiments of the present disclosure.

FIG. 1 is a structural diagram of a display apparatus, in accordance with some embodiments;

FIG. 2 is a three-dimensional diagram of a display substrate, in accordance with some embodiments;

FIG. 3 is a sectional view of the display substrate in FIG. 2 taken along the line AA′, in accordance with some embodiments;

FIGS. 4 and 5 are each a diagram showing an arrangement structure of sub-pixels in a display substrate, in accordance with some embodiments;

FIG. 6 is a structural diagram of a low-reflection film, in accordance with some embodiments;

FIG. 7 is another sectional view of the display substrate in FIG. 2 taken along the line AA′, in accordance with some embodiments;

FIG. 8 is yet another sectional view of the display substrate in FIG. 2 taken along the line AA′, in accordance with some embodiments;

FIG. 9 is a comparison diagram showing a display effect of a display apparatus in some embodiments and display effects of other display apparatuses;

FIG. 10 is a comparison diagram showing reflectivity of low-reflection films with different thicknesses of first inorganic layers to incident light, in accordance with some embodiments;

FIGS. 11 and 12 are comparison diagrams showing fluctuation ranges of reflectivity of low-reflection films with different thicknesses to incident light, in accordance with some embodiments;

FIG. 13 is a comparison diagram showing reflectivity of low-reflection films with different thicknesses of second inorganic layers to incident light, in accordance with some embodiments; and

FIGS. 14 to 18 are each a flowchart of a manufacturing method for a display substrate, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms such as “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if”, depending on the context, is optionally construed as “when”, “in a case where”, “in response to determining”, or “in response to detecting”. Similarly, depending on the context, the phrase “if it is determined” or “if [a stated condition or event] is detected” is optionally construed as “in a case where it is determined”, “in response to determining”, “in a case where [the stated condition or event] is detected”, or “in response to detecting [the stated condition or event]”.

The phrase “applicable to” or “configured to” as used herein indicates an open and inclusive expression, which does not exclude devices that are applicable to or configured to perform additional tasks or steps.

In addition, the phrase “based on” as used herein is meant to be open and inclusive, since a process, step, calculation or other action that is “based on” one or more of the stated conditions or values may, in practice, be based on additional conditions or values beyond those stated.

As used herein, the term such as “parallel”, “perpendicular”, or “equal” includes a stated condition and a condition similar to the stated condition. A range of the similar condition is in an acceptable range of deviation, and the acceptable range of deviation is determined by a person of ordinary skill in the art in view of measurement in question and errors associated with the measurement of a particular quantity (i.e., the limitation of the measurement system). For example, the term “parallel” includes absolute parallelism and approximate parallelism, and an acceptable range of deviation of the approximate parallelism may be, for example, a deviation within 5°. The term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be, for example, a difference between two equals being less than or equal to 5% of any one of the two equals.

It should be understood that, in a case where a layer or element is referred to be on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in apparatuses, and are not intended to limit the scope of the exemplary embodiments.

At present, a display substrate includes light-emitting regions configured to arrange light-emitting devices therein, and a non-light-emitting region other than the light-emitting regions. A black matrix organic film layer is provided in the non-light-emitting region. The black matrix organic film layer can shield metal wires inside the display substrate, thereby reducing or even eliminating reflection of the metal wires on incident light entering the display apparatus in ambient light, and ensuring that the display apparatus has light emission uniformity and an overall black display effect.

However, the inventors of the present disclosure have discovered through research that the black matrix organic film layer has a poor light-shielding effect. The black matrix organic film layer absorbs a small amount of light from incident light that would otherwise direct towards the metal wires, which causes more light to be reflected by the metal wires, and results in a poor overall black display effect of the display apparatus. Furthermore, after the black matrix organic film layer is formed, during a laser etching process of metal leads located on a side of the display substrate, a portion of the black matrix organic film layer close to the metal leads is easily damaged by the high temperature, thereby reducing the manufacturing yield of the display apparatus.

In light of this, embodiments of the present disclosure provide a low-reflection film, a display substrate and a manufacturing method therefor, and a display apparatus, to overcome the above problems. The description will be made below.

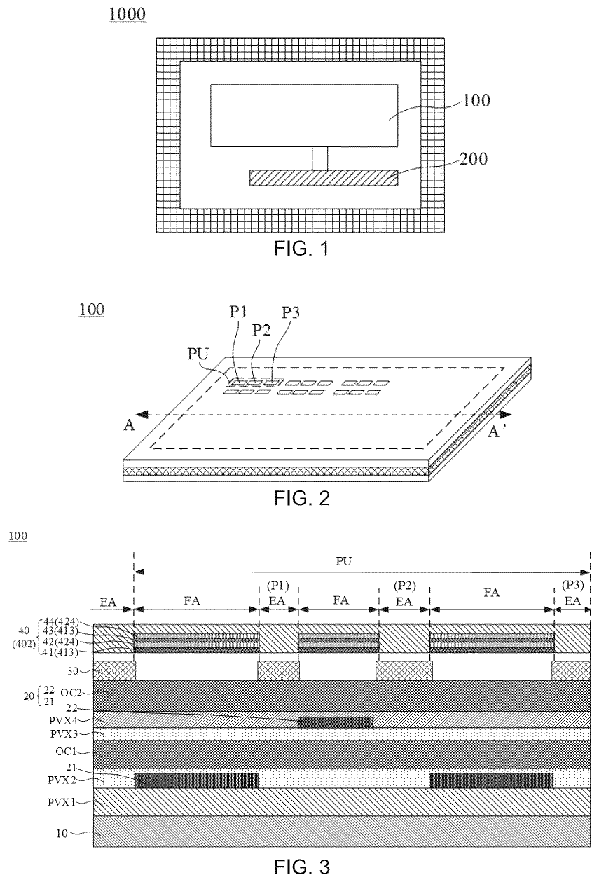

FIG. 1 is a structural diagram of a display apparatus, in accordance with some embodiments.

Referring to FIG. 1, some embodiments of the present disclosure provide a display apparatus 1000. The display apparatus 1000 may be used to display static images or dynamic images. For example, the display apparatus 1000 may be an OLED display apparatus, a Mini LED display apparatus or a Micro LED display apparatus. For example, the display apparatus 1000 may be a small and medium sized display apparatus such as a tablet computer, a smart phone, a head-mounted display, an automobile navigation unit, a camera, a central information display (CID) in a vehicle, a wristwatch-type display apparatus or any other wearable device, a personal digital assistant (PDA), a portable multimedia player (PMP), or a game console; or the display apparatus 1000 may be a medium and large sized electronic apparatus such as a television, an external billboard, a monitor, a home appliance including a display screen, a personal computer, or a laptop computer. The above electronic apparatus may be only an example of application of the display apparatus 1000, and a person of ordinary skill in the art can recognize that the display apparatus 1000 may also be any other electronic apparatus without departing from the spirit and scope of the present disclosure.

As shown in FIG. 1, the display apparatus 1000 can include a display substrate 100 and a circuit board 200, and the display substrate 100 is coupled to the circuit board 200. The circuit board 200 is located on a non-light-exit side of the display substrate 100 (i.e., a side opposite to a display side of the display substrate 100). For example, the circuit board 200 may be a flexible printed circuit board (FPC) or a printed circuit board. The circuit board 200 may provide light-emitting data signals, and the display substrate 100 emits light based on the light-emitting data signals provided by the circuit board 200.

FIG. 2 is a three-dimensional diagram of a display substrate, in accordance with some embodiments. FIG. 3 is a sectional view of the display substrate in FIG. 2 taken along the line AA′, in accordance with some embodiments.

Referring to FIGS. 2 and 3, some embodiments of the present disclosure provide a display substrate 100. The display substrate 100 is a display component capable of emitting display light. The display substrate 100 may emit monochromatic light (light of a single color) or colored light. The display substrate 100 may be applied to the display apparatus 1000 described above. For example, the display substrate 100 is an OLED display substrate, a Mini LED display substrate, or a Micro LED display substrate, etc., which is not limited here.

In some embodiments, as shown in FIG. 3, the display substrate 100 can include a base substrate 10, a plurality of metal wires 20, light-emitting units 30, and low-reflection film(s) 40.

The display substrate 100 further includes at least one display side, where the display side can be understood as a side where the human eyes can see the display light. In some examples, the display substrate 100 includes one display side. For example, the display substrate 100 may be a top-emission display substrate 100, and the light-exit side and display side of the top-emission display substrate 100 are both a side of the light-emitting units 30 away from the base substrate 10. For another example, the display substrate 100 may be a bottom-emission display substrate 100, and the light-exit side and display side of the bottom-emission display substrate 100 are both a side of the light-emitting units 30 close to the base substrate 10. In some other examples, the display substrate 100 may be a double-sided-emission display substrate 100, and the display substrate 100 includes two display sides. The two display sides of the double-sided-emission display substrate 100 are respectively the side of the light-emitting units 30 away from the base substrate 10 and a side of the light-emitting units 30 close to the base substrate 10.

The base substrate 10 is defined to have light-emitting regions EA and a non-light-emitting region FA other than the light-emitting regions. The plurality of metal wires 20 are located on a side of the base substrate 10, and the light-emitting units 30 are located on a side of the plurality of metal wires 20 away from the base substrate 10. The low-reflection film(s) 40 may be located on at least one side of the plurality of metal wires 20. It can be understood that the low-reflection film 40 may be located on one side of the plurality of metal wires 20, or the low-reflection films 40 may be located on both sides of the plurality of metal wires 20. The low-reflection film(s) 40 and the plurality of metal wires 20 are both disposed in the non-light-emitting region FA, which may reduce the shielding of the display light by the low-reflection film 40 and the plurality of metal wires 20 and ensure the light extraction efficiency of the display substrate 100.

In this way, the incident light entering the display apparatus 1000 in the ambient light first enters the low-reflection film 40 and then directs towards the plurality of metal wires 20. The low-reflection film 40 may block and absorb most of the incident light that would otherwise direct towards the metal wires.

The following is a detailed description for the base substrate 10, the plurality of metal wires 20, the light-emitting units 30, and the low-reflection film 40 in the display substrate 100.

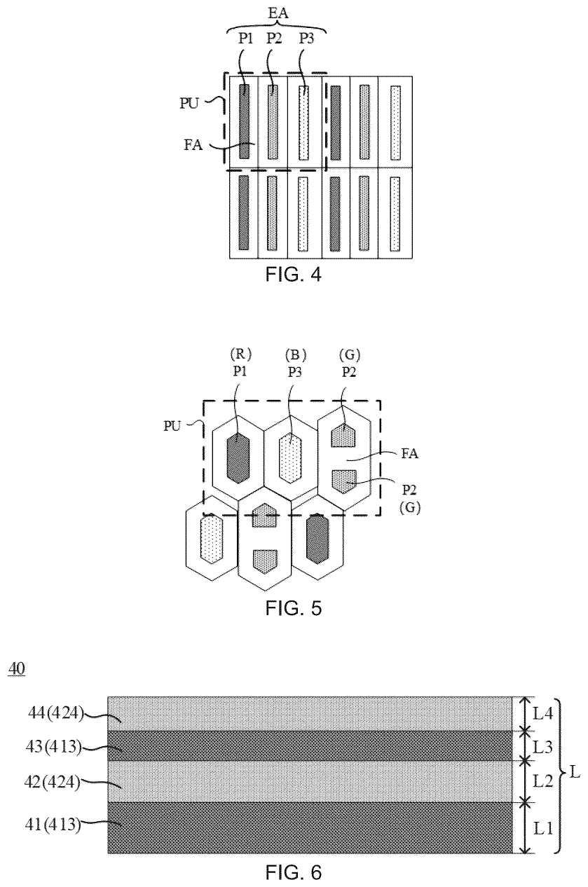

FIGS. 4 and 5 are each a diagram showing an arrangement structure of sub-pixels in a display substrate, in accordance with some embodiments.

As shown in FIG. 3, the base substrate 10 may include a plurality of pixel unit regions PU arranged repeatedly, and each pixel unit region PU may include light-emitting regions EA and portions of the non-light-emitting region FA.

In some examples, as shown in FIG. 4, the light-emitting regions EA of each pixel unit region PU includes a first sub-pixel region P1, a second sub-pixel region P2 and a third sub-pixel region P3 that display different colors. For example, the first sub-pixel region P1 is configured to display blue light, the second sub-pixel region P2 is configured to display green light, and the third sub-pixel region P3 is configured to display red light.

The non-light-emitting region FA may be located between the first sub-pixel region P1 and the second sub-pixel region P2, between the second sub-pixel region P2 and the third sub-pixel region P3, and between the third sub-pixel region P3 and the first sub-pixel region P1 that are located in different pixel unit regions PU, respectively.

In some examples, as shown in FIG. 5, each pixel unit region PU includes one first sub-pixel region P1, two second sub-pixel regions P2 and one third sub-pixel region P3. The one first sub-pixel region P1, the two second sub-pixel regions P2 and the one third sub-pixel region P3 are arranged at intervals. In this case, the two second sub-pixel regions P2 may have the non-light-emitting region FA therebetween.

For example, in the Mini LED display substrate 100, the base substrate 10 may be a glass substrate or a printed circuit board (PCB) substrate.

As shown in FIG. 3, the display substrate 100 includes a plurality of pixel circuits located between the base substrate 10 and the light-emitting units 30. The plurality of pixel circuits may include the plurality of metal wires 20. The plurality of pixel circuits are coupled to the light-emitting units 30.

For example, a single pixel unit region PU includes a first pixel circuit, a second pixel circuit, and a third pixel circuit. For example, the first pixel circuit is located in the first sub-pixel region P1, the second pixel circuit is located in the second sub-pixel region P2, and the third pixel circuit is located in the third sub-pixel region P3. For another example, thin film transistor(s) in at least one of the first pixel circuit, the second pixel circuit, and the third pixel circuit may be located in the non-light-emitting region FA.

A structure of the pixel circuit varies and can be selected according to actual needs. For example, the pixel circuit may include at least two transistors and at least one capacitor. For example, the pixel circuit may have a “2T1C” structure, a “6T1C” structure, a “7T1C” structure, a “6T2C” structure, a “7T2C” structure, or the like. Here, “T” represents a transistor, the number before “T” represents the number of transistors, “C” represents a storage capacitor, and the number before “C” represents the number of storage capacitors. For example, the transistor in the pixel circuit may be a thin film transistor including polycrystalline silicon or a thin film transistor including oxide semiconductor.

In some examples, as shown in FIG. 3, the plurality of metal wires 20 include a plurality of first metal wires 21 and a plurality of second metal wires 22. The plurality of second metal wires 22 may be located on a side of the plurality of first metal wires 21 away from the base substrate 10.

A first insulating layer PVX1 can be included between the base substrate 10 and the plurality of first metal wires 21. A second insulating layer PVX2, a first adhesive layer OC1 and a third insulating layer PVX3 are stacked in sequence on a surface of the plurality of first metal wires 21 close to the plurality of second metal wires 22, and the second insulating layer PVX2, the first adhesive layer OC1 and the third insulating layer PVX3 are located between the plurality of first metal wires 21 and the plurality of second metal wires 22. First through holes (not shown in the figure) may be provided in the second insulating layer PVX2, the first adhesive layer OC1 and the third insulating layer PVX3. The first through hole is located in a region where an orthographic projection of the first metal wire 21 on the base substrate 10 overlaps with an orthographic projection of the second metal wire 22 on the base substrate 10. A first conductive member (not shown in the figure) is provided inside the first through hole. Two ends of the first conductive member are coupled to the first metal wire 21 and the second metal wire 22, respectively. The first conductive member may be used to achieve electrical connection between the first metal wire 21 and the second metal wire 22.

The plurality of metal wires 20 and the light-emitting units 30 are also provided with an insulating layer therebetween. For example, a fourth insulating layer PVX4 is provided between the plurality of second metal wires 22 and the light-emitting units 30, and the fourth insulating layer PVX4 covers both the third insulating layer PVX3 and the plurality of second metal wires 22. A second adhesive layer OC2 is provided on a surface of the fourth insulating layer PVX4 away from the plurality of second metal wires 22. Second through holes (not shown in the figure) may be provided in the second adhesive layer OC2 and the fourth insulating layer PVX4. The second through hole is located in a region where an orthographic projection of the second metal wire 22 on the base substrate 10 overlaps with an orthographic projection of an electrode of the light-emitting unit 30 on the base substrate 10. A second conductive member (not shown in the figure) is provided inside the second through hole. Two ends of the second conductive member are coupled to the second metal wire 22 and the electrode of the light-emitting unit 30, respectively. The second conductive members may be used to achieve electrical connection between the plurality of metal wires 20 and the electrodes of the light-emitting units 30.

For example, materials of the first insulating layer PVX1, the second insulating layer PVX2, the third insulating layer PVX3, and the fourth insulating layer PVX4 may all be silicon nitride. The materials of the first insulating layer PVX1, the second insulating layer PVX2, the third insulating layer PVX3, and the fourth insulating layer PVX4 may be the same or different.

For example, materials of the first adhesive layer OC1 and the second adhesive layer OC2 may be optically clear adhesive.

For example, the plurality of first metal wires 21 may include power signal lines and data signal lines, and the power signal lines and the data signal lines may be arranged in the same layer. The plurality of second metal wires 22 may include a plurality of transition elements.

For example, a material of the metal wire includes copper metal.

As shown in FIG. 3, the light-emitting units 30 may include a plurality of light-emitting devices. The plurality of light-emitting devices may be coupled to the plurality of pixel circuits. For example, the plurality of light-emitting devices may be coupled to the plurality of pixel circuits in a one-to-on correspondence. For another example, at least two light-emitting devices may be coupled to one pixel circuit.

For example, the light-emitting device includes an OLED, a Mini LED, or a Micro LED.

FIG. 6 is a structural diagram of a low-reflection film, in accordance with some embodiments.

In some embodiments, as shown in FIG. 6, the low-reflection film 40 may include a plurality of metal layers 413 and a plurality of inorganic layers 424, and the plurality of metal layers 413 and the plurality of inorganic layers 424 are alternately stacked in sequence. A refractive index of the metal layer 413 is greater than that of the inorganic layer 424.

The number of the metal layers 413 is at least two, and the number of the inorganic layers 424 is also at least two. The number of the metal layers 413 may be the same as or different from the number of the inorganic layers 424.

For example, a material of the metal layer 413 includes at least one of molybdenum, copper, aluminum, silver, and an alloy thereof.

For example, there is a high requirement for light transmittance of the inorganic layer 424, and the inorganic layer 424 needs to have the ability to isolate the inorganic layer 424 from water and oxygen corrosion. For example, a material of the inorganic layer 424 includes silicon nitride, silicon dioxide, or silicon trioxide.

It should be noted that, in the low-reflection film 40 of the double-sided-emission display apparatus 1000, the materials of the plurality of inorganic layers 424 are the same. In the low-reflection film 40 of each of other display apparatuses 1000 other than the double-sided-emission display apparatus 1000, the materials of the plurality of inorganic layers 424 may be the same or different. The materials of the plurality of metal layers 413 in the low-reflection film 40 of the display apparatus 1000 may be the same or different.

In some examples, as shown in FIG. 6, the low-reflection film 40 includes two metal layers 413 and two inorganic layers 424, the two metal layers 413 include a first metal layer 41 and a second metal layer 43, and the two inorganic layers 424 include a first inorganic layer 42 and a second inorganic layer 44. The first inorganic layer 42 is located on a side of the first metal layer 41, the second metal layer 43 is located on a side of the first inorganic layer 42 away from the first metal layer 41, and the second inorganic layer 44 is located on a side of the second metal layer 43 away from the first inorganic layer 42. A refractive index of the first inorganic layer 42 is less than a refractive index of the first metal layer 41, a refractive index of the second metal layer 43 is greater than the refractive index of the first inorganic layer 42, and a refractive index of the second inorganic layer 44 is less than the refractive index of the second metal layer 43.

For example, materials of the first metal layer 41 and the second metal layer 43 may both include molybdenum metal. For example, the refractive indexes of the first metal layer 41 and the second metal layer 43 may both be 2.3.

For example, materials of the first inorganic layer 42 and the second inorganic layer 44 may both include silicon nitride. For example, refractive indexes of the first inorganic layer 42 and the second inorganic layer 44 may both be 2.

In this way, refractive indexes of the first metal layer 41, the first inorganic layer 42, the second metal layer 43 and the second inorganic layer 44 shows a high-low-high-low pattern, and the incident light entering the low-reflection film 40 may be refracted or totally reflected at an interface between adjacent layers in the second inorganic layer 44, the second metal layer 43, the first inorganic layer 42 and the first metal layer 41. Therefore, the incident light entering the low-reflection film 40 may undergo multiple refractions or total reflections in the low-reflection film 40. As a result, the energy of the incident light may be consumed during the multiple refractions or total reflections, thereby increasing the amount of incident light absorbed and blocked by the low-reflection film 40, reducing the reflectivity of the low-reflection film 40 to the incident light, and improving the light-shielding effect of the low-reflection film 40. In addition, coherent light may be generated during the multiple refractions or total reflection, and destructive interference is likely to occur between two columns of coherent light at the peak and the trough, which may further increase the amount of incident light absorbed and blocked by the low-reflection film 40, further reduce the reflectivity of the low-reflection film 40 to the incident light, and further improve the light-shielding effect of the low-reflection film 40.

In some examples, the low-reflection film 40 may include N metal layers 413 and a plurality of inorganic layers 424, and the N metal layers 413 and the plurality of inorganic layers 424 are alternately stacked in sequence. N is a positive integer greater than or equal to three. For example, N may be three, four, five or six.

For example, the low-reflection film 40 includes three metal layers 413 and three inorganic layers 424, and the three metal layers 413 and the three inorganic layers 424 are alternately stacked in sequence. For another example, the low-reflection film 40 includes three metal layers 413 and four inorganic layers 424, the three metal layers 413 and three of the four inorganic layers 424 are alternately stacked in sequence, and the remaining one of the four inorganic layers 424 is located on a side of the three inorganic layers 424 away from the metal layers 413.

In this way, the incident light entering the low-reflection film 40 may be refracted or totally reflected at an interface between adjacent layers in the N metal layers 413 and the plurality of inorganic layers 424, and thus the incident light entering the low-reflection film 40 may undergo more refractions or total reflections in the low-reflection film 40. As a result, the low-reflection film 40 may consume more energy of the incident light, and destructive interference is more likely to occur during multiple refractions or total reflections, which may greatly increase the amount of incident light absorbed and blocked by the low-reflection film 40, reduce the reflectivity of the low-reflection film 40 to the incident light, and thereby greatly improve the light-shielding effect of the low-reflection film 40.

In some embodiments, as shown in FIG. 6, in a direction perpendicular to the first metal layer 41, a dimension L of the low-reflection film 40 is greater than or equal to 1800 Å and less than or equal to 2500 Å. For example, L may be 1800 Å, 1850 Å, 1876.5 Å, 1895 Å, 1900 Å, 1950 Å, 2000 Å, 2050 Å, 2100 Å, 2200 Å, 2350 Å, 2400 Å, 2450 Å, or 2500 Å.

Compared with the black matrix organic film layer, the dimension L (i.e., thickness) of the low-reflection film 40 is relatively small, which is beneficial to reducing the overall thickness of the display substrate 100.

In some embodiments, as shown in FIG. 6, in the direction perpendicular to the first metal layer 41, a dimension L1 of the first metal layer 41 is greater than a dimension L2 of the first inorganic layer 42.

In this way, the optical path of the incident light entering the first metal layer 41 after being refracted at the interface between the first inorganic layer 42 and the first metal layer 41 may be extended, which may consume the energy of the incident light, reduce the reflectivity of the low-reflection film 40 to the incident light, and thereby improve the light-shielding effect of the low-reflection film 40.

In some examples, in the direction perpendicular to the first metal layer 41, a ratio of the dimension L1 of the first metal layer 41 to the dimension L2 of the first inorganic layer 42 is greater than or equal to 2.5 and less than or equal to 3.5. For example, the ratio of L1 to L2 may be 2.5, 2.66, 2.7, 2.8, 2.9, 3.0, 3.12, 3.2, 3.35, 3.4, or 3.5.

In this way, the optical path of the incident light entering the first metal layer 41 after being refracted at the interface between the first inorganic layer 42 and the first metal layer 41 may be reasonably extended, which may consume more energy of the incident light, greatly reduce the reflectivity of the low-reflection film 40 to the incident light, and further improve the light-shielding effect of the low-reflection film 40.

In some embodiments, as shown in FIG. 6, in the direction perpendicular to the first metal layer 41, the dimension L1 of the first metal layer 41 is greater than a dimension L3 of the second metal layer 43.

In this way, the transmittance of the metal layer is less than that of the inorganic layer, and the dimension of the second metal layer 43 is relatively small, so that the energy of the incident light may be stably consumed during refraction or total reflection of the incident light at the interface between the second inorganic layer 44 and the second metal layer 43, and at the interface between the second metal layer 43 and the first inorganic layer 42. Thus, on the basis of ensuring the light-shielding effect of the low-reflection film 40, the fluctuation range of the reflectivity of the low-reflection film 40 to the incident light is relatively small, thereby making the stability and uniformity of the light-shielding effect of the low-reflection film 40 relatively high.

In some examples, in the direction perpendicular to the first metal layer 41, a ratio of the dimension L1 of the first metal layer 41 to the dimension L3 of the second metal layer 43 is greater than or equal to 11.5 and less than or equal to 17.5. For example, the ratio of L1 to L3 may be 11.5, 12.2, 12.5, 13.1, 13.5, 14.2, 14.5, 15.2, 15.5, 15.8, 16.2, 16.5, 16.9, or 17.5.

By reasonably limiting the ratio of the dimension L1 of the first metal layer 41 to the dimension L3 of the second metal layer 43, the energy of the incident light may be consumed more stably during refraction or total reflection of the incident light at the interface between the first inorganic layer 42 and the second metal layer 43, and at the interface between the second inorganic layer 44 and the second metal layer 43. This allows the fluctuation range of the reflectivity of the low-reflection film 40 to the incident light to be as small as possible while ensuring the light-shielding effect of the low-reflection film 40, thereby greatly improving the stability and uniformity of the light-shielding effect of the low-reflection film 40.

In some embodiments, as shown in FIG. 6, in the direction perpendicular to the first metal layer 41, the dimension L1 of the first metal layer 41 is greater than a dimension L4 of the second inorganic layer 44.

In this way, the dimension of the second inorganic layer 44 is relatively small, which may make the incident light easily refracted or totally reflected at the interface between the second inorganic layer 44 and the second metal layer 43, thereby consuming the energy of the incident light, reducing the reflectivity of the low-reflection film 40 to the incident light, and improving the light-shielding effect of the low-reflection film 40.

In some examples, in the direction perpendicular to the first metal layer 41, a ratio of the dimension L1 of the first metal layer 41 to the dimension L4 of the second inorganic layer 44 is greater than or equal to 2 and less than or equal to 3. For example, the ratio of L1 to L4 may be 2, 2.1, 2.3, 2.35, 2.36, 2.4, 2.5, 2.6, 2.7, 2.8, 2.85, 2.9, or 3.

By reasonably limiting the ratio of the dimension L1 of the first metal layer 41 to the dimension L4 of the second inorganic layer 44, the incident light may be more easily refracted or totally reflected at the interface between the second inorganic layer 44 and the second metal layer 43, thereby consuming more energy of the incident light, greatly reducing the reflectivity of the low-reflection film 40 to the incident light, and greatly improving the light-shielding effect of the low-reflection film 40.

In some embodiments, as shown in FIG. 6, in the direction perpendicular to the first metal layer 41, the dimension L2 of the first inorganic layer 42 is greater than the dimension L3 of the second metal layer 43.

In this way, the incident light may be easily refracted or totally reflected at the interface between the second inorganic layer 44 and the second metal layer 43, and at the interface between the second metal layer 43 and the first inorganic layer 42, thereby consuming the energy of the incident light and improving the light-shielding effect of the low-reflection film 40. Moreover, since the dimension of the second metal layer 43 is relatively small, the energy of the incident light may be stably consumed during refraction or total reflection of the incident light at the interface between the second inorganic layer 44 and the second metal layer 43, and at the interface between the second metal layer 43 and the first inorganic layer 42. Thus, on the basis of improving the light-shielding effect of the low-reflection film 40, the fluctuation range of the reflectivity of the low-reflection film 40 to the incident light is relatively small, thereby making the stability and uniformity of the light-shielding effect of the low-reflection film 40 relatively high.

In some examples, in the direction perpendicular to the first metal layer 41, a ratio of the dimension L2 of the first inorganic layer 42 to the dimension L3 of the second metal layer 43 is greater than or equal to 4 and less than or equal to 6.5. For example, the ratio of L2 to L3 may be 4, 4.2, 4.5, 4.9, 5, 5.2, 5.5, 5.8, 6, 6.3, or 6.5.

By reasonably limiting the ratio of the dimension L2 of the first inorganic layer 42 to the dimension L3 of the second metal layer 43, the incident light may be more easily refracted or totally reflected at the interface between the second inorganic layer 44 and the second metal layer 43, and at the interface between the second metal layer 43 and the first inorganic layer 42, thereby consuming more energy of the incident light and greatly improving the light-shielding effect of the low-reflection film 40. Moreover, the energy of the incident light may be consumed more stably during refraction or total reflection of the incident light at the interface between the second inorganic layer 44 and the second metal layer 43, and at the interface between the second metal layer 43 and the first inorganic layer 42. This allows the fluctuation range of the reflectivity of the low-reflection film 40 to the incident light to be as small as possible on the basis that the light-shielding effect of the low-reflection film 40 is greatly improved, thereby greatly improving the stability and uniformity of the light-shielding effect of the low-reflection film 40.

In some embodiments, as shown in FIG. 6, in the direction perpendicular to the first metal layer 41, the dimension L4 of the second inorganic layer 44 is greater than the dimension L3 of the second metal layer 43.

Since the dimension of the second metal layer 43 is relatively small, the energy of the incident light may be stably consumed during refraction or total reflection of the incident light at the interface between the second inorganic layer 44 and the second metal layer 43, and at the interface between the second metal layer 43 and the first inorganic layer 42. Thus, on the basis of ensuring the light-shielding effect of the low-reflection film 40, the fluctuation range of the reflectivity of the low-reflection film 40 to the incident light is relatively small, thereby improving the stability and uniformity of the light-shielding effect of the low-reflection film 40.

In some examples, in the direction perpendicular to the first metal layer 41, a ratio of the dimension L4 of the second inorganic layer 44 to the dimension L3 of the second metal layer 43 is greater than or equal to 4.5 and less than or equal to 7. For example, the ratio of L4 to L3 may be 4.5, 4.8, 5, 5.4, 5.54, 5.6, 5.8, 6, 6.2, 6.4, 6.8, 6.9, or 7.

By reasonably limiting the ratio of the dimension L4 of the second inorganic layer 44 to the dimension L3 of the second metal layer 43, the energy of the incident light may be consumed more stably during refraction or total reflection of the incident light at the interface between the second inorganic layer 44 and the second metal layer 43, and at the interface between the second metal layer 43 and the first inorganic layer 42. Thus, on the basis of ensuring the light-shielding effect of the low-reflection film 40, the fluctuation range of the reflectivity of the low-reflection film 40 to the incident light is smaller, thereby greatly improving the stability and uniformity of the light-shielding effect of the low-reflection film 40.

In some examples, as shown in FIG. 6, in the direction perpendicular to the first metal layer 41, the dimension L1 of the first metal layer 41 is greater than or equal to 1000 Å and less than or equal to 1100 Å. For example, L1 may be 1000 Å, 1020 Å, 1050 Å, 1080 Å, or 1100 Å.

In some examples, as shown in FIG. 6, in the direction perpendicular to the first metal layer 41, the dimension L2 of the first inorganic layer 42 is greater than or equal to 350 Å and less than or equal to 395 Å. For example, L2 may be 350 Å, 360 Å, 376 Å, 380 Å, 390 Å, or 395 Å.

In some examples, as shown in FIG. 6, in the direction perpendicular to the first metal layer 41, the dimension L3 of the second metal layer 43 is greater than or equal to 65 Å and less than or equal to 85 Å. For example, L3 may be 65 Å, 68 Å, 70 Å, 76.5 Å, 80 Å, or 85 Å.

In some examples, as shown in FIG. 6, in the direction perpendicular to the first metal layer 41, the dimension L4 of the second inorganic layer 44 is greater than or equal to 400 Å and less than or equal to 450 Å. For example, L4 may be 400 Å, 405 Å, 410 Å, 420 Å, 424 Å, 435 Å, 440 Å, 445 Å, or 450 Å.

In a case where a wavelength of the incident light is greater than or equal to 400 nm and less than or equal to 700 nm (e.g., the wavelength is 400 nm, 420 nm, 480 nm, 500 nm, 550 nm, 600 nm, 650 nm or 700 nm), the reflectivity of the low-reflection film 40 to the incident light is greater than or equal to 2.5% and less than or equal to 4% (e.g., the reflectivity is 2.5%, 2.6%, 2.8%, 3%, 3.25%, 3.65%, 3.85% or 4%), and a difference between the maximum and minimum values of the reflectivity of the low-reflection film 40 to the incident light is greater than or equal to 0.5% and less than or equal to 1.5% (e.g., the difference is 0.5%, 0.6%, 0.8%, 0.85%, 1%, 1.05%, 1.15%, 1.25%, 1.38% or 1.5%).

By reasonably limiting the dimension L1 of the first metal layer 41, the dimension L2 of the first inorganic layer 42, the dimension L3 of the second metal layer 43 and the dimension L4 of the second inorganic layer 44, it may be possible to increase the number of times the incident light entering the low-reflection film 40 is refracted or totally reflected at the interface between adjacent layers in the second inorganic layer 44, the second metal layer 43, the first inorganic layer 42 and the first metal layer 41, which may extend the optical path of the incident light in the low-reflection film 40. Moreover, destructive interference is more likely to occur during multiple refractions or total reflections, which may consume more energy of the incident light, reduce the reflectivity of the low-reflection film 40 to the incident light, and improve the light-shielding effect of the low-reflection film 40. Furthermore, on the basis of ensuring the light-shielding effect of the low-reflection film 40, the fluctuation range of the reflectivity of the low-reflection film 40 to the incident light is relatively small, thereby improving the stability and uniformity of the light-shielding effect of the low-reflection film 40.

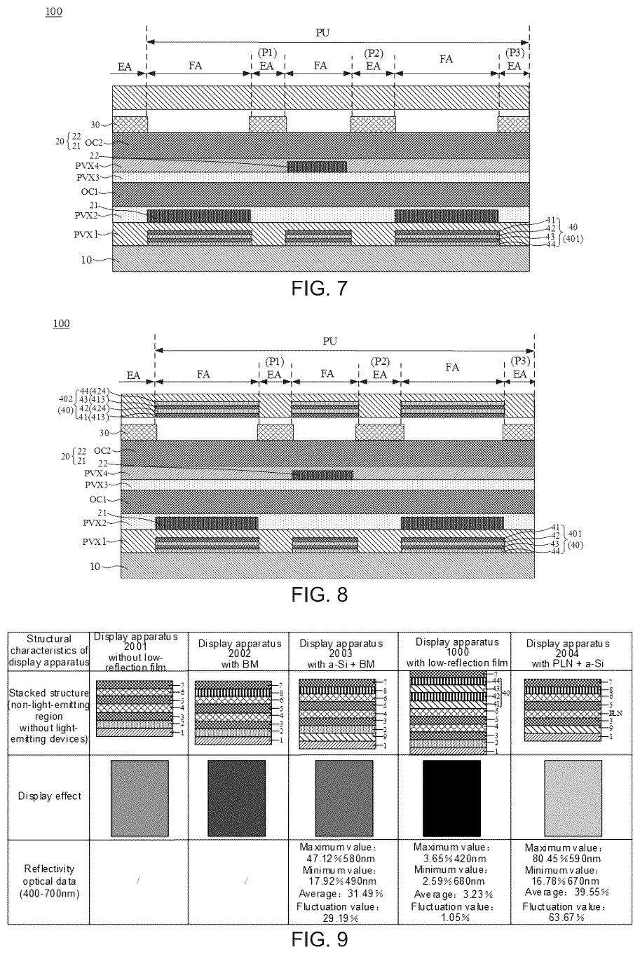

FIG. 7 is another sectional view of the display substrate in FIG. 2 taken along the line AA′, in accordance with some embodiments. FIG. 8 is yet another sectional view of the display substrate in FIG. 2 taken along the line AA′, in accordance with some embodiments.

In some embodiments, as shown in FIGS. 3, 7, 8, the low-reflection film 40 can be located on at least one side of the plurality of metal wires 20 close to the display side(s). It can be understood that one low-reflection film 40 may be located on one side of the plurality of metal wires 20 close to one display side, or two low-reflection films 40 may be located on both sides of the plurality of metal wires 20 close to the two display sides.

Since the metal layer and the inorganic layer in the low-reflection film 40 have good thermal stability and high hardness, after the low-reflection film 40 is formed, the low-reflection film 40 will not be damaged during the laser etching process of metal leads located on the side of the display substrate 100, which may improve the manufacturing yield of the display substrate 100 and the display apparatus 1000. In addition, since the low-reflection film 40 has a good light-shielding effect, the low-reflection film 40 may absorb a large amount of incident light that would otherwise direct towards the metal wires 20, which may make the incident light reflected from the metal wires 20 relatively small, thereby reducing the reflectivity of the metal wires 20 in the display substrate 100 to the incident light, and improving the overall black display effect of the display substrate 100 and the display apparatus 1000. Moreover, since the stability and uniformity of the light-shielding effect of the low-reflection film 40 is relatively high, the fluctuation range of the reflectivity of the metal wires 20 in the display substrate 100 to the incident light is relatively small, which further improves the overall black display effect of the display substrate 100 and the display apparatus 1000.

In some examples, as shown in FIG. 3, the display substrate 100 is a top-emission display substrate 100, and the low-reflection film 40 can be located on a side of the light-emitting units 30 away from the base substrate 10. In some examples, in a case where the display substrate 100 shown in FIG. 7 is a bottom-emission display substrate 100, the low-reflection film 40 can be located between the base substrate 10 and the metal wires 20.

The low-reflection film 40 may block and absorb the incident light that would otherwise direct towards the metal wires 20, so that less incident light may be reflected from the metal wires 20, thereby reducing the reflectivity of the metal wires 20 in the top-emission display substrate 100 or bottom-emission display substrate 100 to the incident light, and improving the overall black display effect of the top-emission display substrate 100 or bottom-emission display substrate 100.

For example, the display substrate 100 may further include a color filter film, and the color filter film may be located on a side of the light-emitting units 30 away from the base substrate 10. The color filter film is disposed in the light-emitting regions EA, and the low-reflection film 40 is disposed in the non-light-emitting region FA. A distance between the color filter film and the base substrate 10 may be the same as or different from a distance between the low-reflection film 40 and the base substrate 10.

For example, the display substrate 100 may further include a touch layer. The touch layer may be located on a side of the light-emitting units 30 away from the base substrate 10, and the low-reflection film 40 may be located on a side of the touch layer away from the light-emitting units 30.

The low-reflection film 40 may block and absorb the incident light that would otherwise direct towards the touch layer, as well as the incident light that would otherwise pass through the touch layer and the light-emitting units 30 and then be incident onto the metal wires 20, so that less incident light may be reflected from the touch layer and the metal wires 20, thereby reducing the reflectivity of the touch layer and the metal wires 20 in the display substrate 100 to the incident light, and improving the display effect of the display substrate 100.

In some examples, as shown in FIGS. 3 and 7, the display substrate 100 is a double-sided-emission display substrate 100, and the low-reflection film(s) 40 can include a first low-reflection film 401 or a second low-reflection film 402. For example, as shown in FIG. 7, the first low-reflection film 401 is located between the base substrate 10 and the plurality of metal wires 20. For another example, in a case where the display substrate 100 in FIG. 3 is the double-sided-emission display substrate 100, the second low-reflection film 402 is located on the side of the light-emitting units 30 away from the base substrate 10.

The low-reflection film 40 may block and absorb the incident light that would otherwise direct from one display side to the metal wires 20, so that less incident light may be reflected from the metal wires 20, thereby reducing the reflectivity of the incident light directing from the one display side to the metal wires 20 in the double-sided-emission display substrate 100, and improving the overall black display effect of the one display side of the double-sided-emission display substrate 100.

In some examples, as shown in FIG. 8, the display substrate 100 is a double-sided-emission display substrate 100, and the low-reflection film(s) 40 can include a first low-reflection film 401 and a second low-reflection film 402. The first low-reflection film 401 is located between the base substrate 10 and the plurality of metal wires 20, and the second low-reflection film 402 is located on the side of the light-emitting units 30 away from the base substrate 10.

The low-reflection films 40 may block and absorb the incident light that would otherwise direct from two display sides to the metal wires 20, so that less incident light may be reflected from the metal wires 20, thereby reducing the reflectivity of the incident light directing from the two display sides to the metal wires 20 in the double-sided-emission display substrate 100, and improving the overall black display effect of the double-sided-emission display substrate 100.

FIG. 9 is a comparison diagram showing a display effect of a display apparatus in some embodiments and display effects of other display apparatuses.

As shown in FIG. 9, in the non-light-emitting region where no light-emitting devices are provided, in a direction perpendicular to the display apparatus, the display apparatus 2001 includes a glass substrate 1, a first insulating layer 2, a second insulating layer 3, a first adhesive layer 4, a third insulating layer 5, a second adhesive layer 6 and a fourth insulating layer 7 stacked in sequence, and no low-reflection film is provided in the display apparatus 2001. Compared with the display apparatus 2001, in the display apparatus 2002, a black matrix (BM) organic film layer 8 is provided between the second adhesive layer 6 and the fourth insulating layer 7. The overall black display effect of the display apparatus 2002 is better than that of the display apparatus 2001. Compared with the display apparatus 2002, in the display apparatus 2003, an amorphous silicon (a-Si) layer 9 is provided between the glass substrate 1 and the first insulating layer 2. The overall black display effect of the display apparatus 2002 is better than that of the display apparatus 2003. Compared with the display apparatus 2002, in the display apparatus 2004, the amorphous silicon (a-Si) layer 9 is used to replace the first insulating layer 2, and a flat layer PLN is used to replace the first adhesive layer 4. The overall thickness of the display apparatus 2004 is thinner, and the overall black display effect of the display apparatus 2002 is better than that of the display apparatus 2004.

As shown in FIG. 9, compared with the display apparatus 2001, the display apparatus 1000 provided in the embodiments of the present disclosure has the low-reflection film 40 disposed between the second adhesive layer 6 and the fourth insulating layer 7. The low-reflection film 40 includes the first metal layer 41, the first inorganic layer 42, the second metal layer 43 and the second inorganic layer 44. Compared with the display apparatuses 2001, 2002, 2003 and 2004, the display apparatus 1000 has the best overall black display effect.

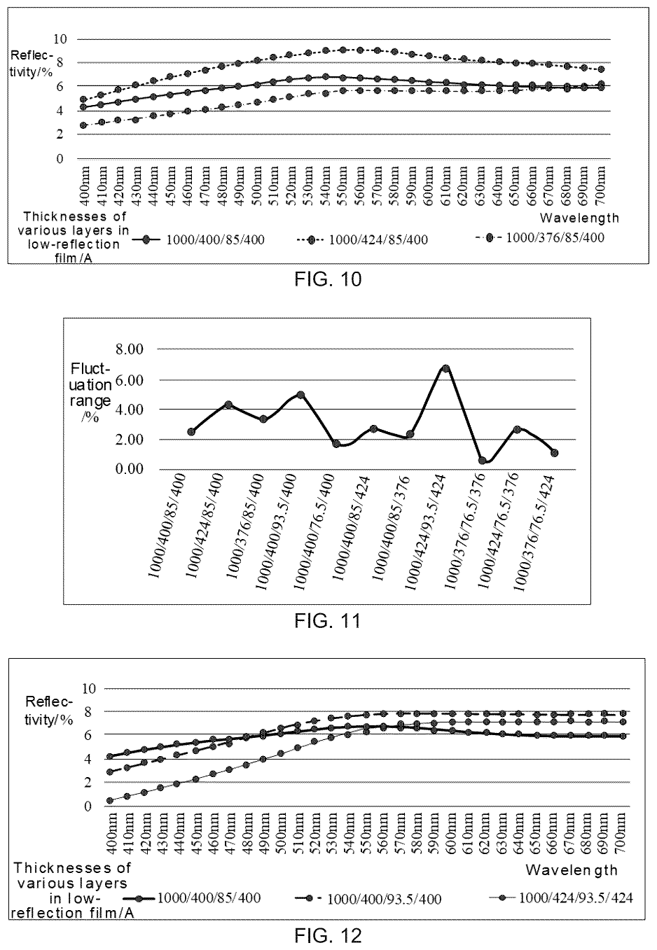

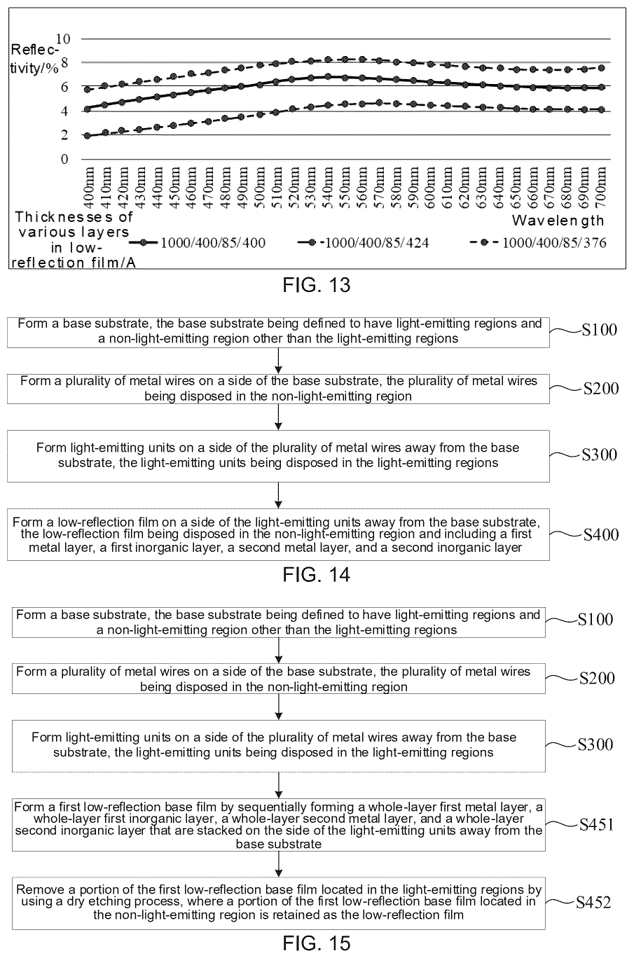

FIG. 10 is a comparison diagram showing reflectivity of low-reflection films with different thicknesses of first inorganic layers to incident light, in accordance with some embodiments. FIGS. 11 and 12 are comparison diagrams showing fluctuation ranges of reflectivity of low-reflection films with different thicknesses to incident light, in accordance with some embodiments. FIG. 13 is a comparison diagram showing reflectivity of low-reflection films with different thicknesses of second inorganic layers to incident light, in accordance with some embodiments.

Schemes 1 to 11 are low-reflection films 40 in which the thickness L1 of the first metal layer 41, the thickness L2 of the first inorganic layer 42, the thickness L3 of the second metal layer 43, and/or the thickness L4 of the second inorganic layer 44 are different. The maximum values, minimum values, and fluctuation ranges of the reflectivity of the low-reflection films 40 in Schemes 1 to 11 to the incident light are shown in Table 1 below.

TABLE 1

| | L1 | L2 | L3 | L4 | Reflectivity (unit: %) | | |
|---|---|---|---|---|---|---|---|
| | (unit: Å) | (unit: Å) | (unit: Å) | (unit: Å) | Max | Min | Fluctuation |
| Scheme 1 | 1000 | 400 | 85 | 400 | 6.74 | 4.24 | 2.49 |
| Scheme 2 | 1000 | 424 | 85 | 400 | 9.07 | 4.84 | 4.23 |
| Scheme 3 | 1000 | 376 | 85 | 400 | 6.14 | 2.80 | 3.35 |
| Scheme 4 | 1000 | 400 | 93.5 | 400 | 7.84 | 2.95 | 4.89 |
| Scheme 5 | 1000 | 400 | 76.5 | 400 | 6.23 | 4.52 | 1.71 |
| Scheme 6 | 1000 | 400 | 85 | 424 | 4.71 | 2.03 | 2.68 |
| Scheme 7 | 1000 | 400 | 85 | 376 | 8.26 | 5.90 | 2.36 |
| Scheme 8 | 1000 | 424 | 93.5 | 424 | 7.16 | 0.46 | 6.70 |
| Scheme 9 | 1000 | 376 | 76.5 | 376 | 5.96 | 5.34 | 0.62 |
| Scheme 10 | 1000 | 424 | 76.5 | 376 | 9.37 | 6.73 | 2.64 |
| Scheme 11 | 1000 | 376 | 76.5 | 424 | 3.65 | 2.60 | 1.05 |

In Table 1, “Max” represents the maximum value of the reflectivity of the low-reflection film 40 to the incident light; “Min” represents the minimum value of the reflectivity of the low-reflection film 40 to the incident light; and “Fluctuation” represents the difference between the maximum value of the reflectivity of the low-reflection film 40 to the incident light and the minimum value of the reflectivity of the low-reflection film 40 to the incident light (i.e., the fluctuation range of the reflectivity of the low-reflection film 40 to the incident light).

Referring to FIG. 10 and the data in Table 1, it can be seen that the thickness L2 of the first inorganic layer 42 is positively correlated with the reflectivity of the low-reflection film 40 to the incident light. That is, the greater the thickness L2 of the first inorganic layer 42, the greater the reflectivity of the corresponding low-reflection film 40 to the incident light.

Referring to FIGS. 11 and 12, as well as the data in Table 1, it can be seen that there is no obvious correlation between the thickness L3 of the second metal layer 43 and the reflectivity of the low-reflection film 40 to the incident light. However, there is a positive correlation between the thickness L3 of the second metal layer 43 and the fluctuation range of the reflectivity of the low-reflection film 40 to the incident light. That is, the smaller the thickness L3 of the second metal layer 43, the smaller the fluctuation range of the reflectivity of the corresponding low-reflection film 40 to the incident light.

Referring to FIG. 13 and the data in Table 1, it can be seen that the thickness L4 of the second inorganic layer 44 is negatively correlated with the reflectivity of the low-reflection film 40 to the incident light. That is, the greater the thickness L4 of the second inorganic layer 44, the smaller the reflectivity of the corresponding low-reflection film 40 to the incident light.

In summary, in the low-reflection film 40, the display substrate 100 and the display apparatus 1000 provided in the embodiments of the present disclosure, the refractive indexes of the first metal layer 41, the first inorganic layer 42, the second metal layer 43 and the second inorganic layer 44 shows a high-low-high-low pattern, and the incident light entering the low-reflection film 40 may be refracted or totally reflected at an interface between adjacent layers in the second inorganic layer 44, the second metal layer 43, the first inorganic layer 42 and the first metal layer 41. Therefore, the incident light entering the low-reflection film 40 may undergo multiple refractions or total reflections in the low-reflection film 40. As a result, the energy of the incident light may be consumed during the multiple refractions or total reflections; coherent light may be generated during the multiple refractions or total reflection, and destructive interference is likely to occur between two columns of coherent light at the peak and the trough, which may further increase the amount of incident light absorbed and blocked by the low-reflection film 40, reduce the reflectivity of the low-reflection film 40 to the incident light, make the light-shielding effect of the low-reflection film 40 relatively good, and make the stability and uniformity of the light-shielding effect of the low-reflection film 40 relatively high. Since the metal layer and the inorganic layer in the low-reflection film 40 have good thermal stability and high hardness, after the low-reflection film 40 is formed, the low-reflection film 40 will not be damaged during the laser etching process of metal leads located on the side of the display substrate 100, which may improve the manufacturing yield of the display substrate 100 and the display apparatus 1000. The low-reflection film 40 may absorb a large amount of incident light that would otherwise direct towards the metal wires 20, which may make the incident light reflected from the metal wires 20 relatively small, thereby reducing the reflectivity of the metal wires 20 in the display substrate 100 to the incident light, and improving the overall black display effect of the display substrate 100 and the display apparatus 1000.

FIGS. 14 to 18 are each a flowchart of a manufacturing method for a display substrate, in accordance with some embodiments.

As shown in FIG. 14, embodiments of the present disclosure further provide a manufacturing method for a display substrate 100, and the manufacturing method can include steps S100 to S300.

In step S100, a base substrate 10 is formed, and the base substrate 10 is defined to have light-emitting regions EA and a non-light-emitting region FA other than the light-emitting regions. The structural features of the base substrate 10 have been described in detail above, which will not be repeated here.

The base substrate 10 may be a rigid base substrate or a flexible base substrate. For example, a material of the base substrate 10 may be polyethylene terephthalate (PET), polyimide (PI), or cyclo olefin polymer (COP).

For example, in the Mini LED display substrate 100, the base substrate 10 may be a glass substrate or a printed circuit board (PCB) substrate.

In step S200, a plurality of metal wires 20 are formed on a side of the base substrate 10, and the plurality of metal wires 20 are disposed in the non-light-emitting region FA.

As shown in FIG. 3, the display substrate 100 includes a plurality of pixel circuits located on the base substrate 10. The plurality of pixel circuits may include the plurality of metal wires 20. The structural features of the pixel circuit have been described in detail above, which will not be repeated here.

The plurality of metal wires 20 can include a plurality of first metal wires 21 and a plurality of second metal wires 22. The plurality of second metal wires 22 may be located on a side of the plurality of first metal wires 21 away from the base substrate 10.

Step S200 may include: forming a first insulating layer PVX1 on the side of the base substrate 10 through a deposition process; forming a first metal material layer of a whole layer on a surface of the first insulating layer PVX1 away from the base substrate 10 by a deposition process; removing a portion of the first metal material layer in the light-emitting regions EA by an etching process, where a corresponding pattern of the first metal material layer in the non-light-emitting region FA is retained to form the plurality of first metal wires 21; forming a second insulating layer PVX2 on surfaces of the first insulating layer PVX1 and the plurality of first metal wires 21 away from the base substrate 10 through a deposition process; forming a first adhesive layer OC1 on a surface of the second insulating layer PVX2 away from the base substrate 10 through coating, exposure and development processes; forming a third insulating layer PVX3 on a surface of the first adhesive layer OC1 away from the base substrate 10 by a deposition process; forming first through holes (not shown in the figure) partially exposing the first metal wires 21 in the second insulating layer PVX2, the first adhesive layer OC1 and the third insulating layer PVX3 by a dry etching process; forming a second metal material layer of a whole layer on a surface of the third insulating layer PVX3 away from the base substrate 10 through a deposition process; and then, removing a portion of the second metal material layer in the light-emitting regions EA by an etching process, where a corresponding pattern of the second metal material layer in the non-light-emitting region FA is retained to form the plurality of second metal wires 22.

The first through hole is located in a region where an orthographic projection of the first metal wire 21 on the base substrate 10 overlaps with an orthographic projection of the second metal wire 22 on the base substrate 10. After the first through hole is formed, a first conductive member (not shown in the figure) is further formed inside the first through hole. Two ends of the first conductive member are coupled to the first metal wire 21 and the second metal wire 22, respectively. The first conductive member may be used to achieve electrical connection between the first metal wire 21 and the second metal wire 22.

After the above step S200, the method further includes: forming, on surfaces of the plurality of second metal wires 22 and the third insulating layer PVX3 away from the plurality of first metal wires 21, a fourth insulating layer PVX4 that covers both the plurality of second metal wires 22 and the third insulating layer PVX3 through a deposition process; and then, forming a second adhesive layer OC2 on a surface of the fourth insulating layer PVX4 away from the plurality of second metal wires 22 through coating, exposure and development processes.

For example, a material of the metal wire includes copper metal.

For example, the plurality of first metal wires 21 may include power signal lines and data signal lines, and the power signal lines and the data signal lines may be arranged in the same layer. The plurality of second metal wires 22 may include a plurality of transition elements.

For example, materials of the first insulating layer PVX1, the second insulating layer PVX2, the third insulating layer PVX3, and the fourth insulating layer PVX4 may all be silicon nitride. The materials of the first insulating layer PVX1, the second insulating layer PVX2, the third insulating layer PVX3, and the fourth insulating layer PVX4 may be the same or different.

For example, materials of the first adhesive layer OC1 and the second adhesive layer OC2 may be optically clear adhesive.

In step S300, light-emitting units 30 are formed on a side of the plurality of metal wires 20 away from the base substrate 10, and the light-emitting units 30 are disposed in the light-emitting regions EA. The light-emitting units 30 may include a plurality of light-emitting devices. The plurality of light-emitting devices may be coupled to the plurality of pixel circuits. For example, the plurality of light-emitting devices may be coupled to the plurality of pixel circuits in a one-to-one correspondence. For another example, at least two light-emitting devices may be coupled to one pixel circuit.

In some examples, as shown in FIG. 3, step S300 may include: forming second through holes partially exposing the second metal wires 22 in the second adhesive layer OC2 and the fourth insulating layer PVX4 by using a dry etching process; and then, forming the light-emitting units 30 composed of the plurality of light-emitting devices on a surface of the second adhesive layer OC2 away from the base substrate 10.

The second through hole is located in a region where an orthographic projection of the second metal wire 22 on the base substrate 10 overlaps with an orthographic projection of an electrode of the light-emitting device in the light-emitting unit 30 on the base substrate 10. After the second through hole is formed, a second conductive member (not shown in the figure) is further formed inside the second through hole. Two ends of the second conductive member are coupled to the second metal wire 22 and the electrode of the light-emitting unit 30, respectively. The second conductive members may be used to achieve electrical connection between the plurality of metal wires 20 and the electrodes of the light-emitting units 30.

For example, the light-emitting device includes an OLED, a Mini LED, or a Micro LED.

As shown in FIG. 14, the display substrate 100 may be a top-emission display substrate 100, a bottom-emission display substrate 100 or a double-sided-emission display substrate 100, and the manufacturing method for the display substrate 100 may further include step S400. In step S400, after step S300, a low-reflection film 40 is formed on a side of the light-emitting units 30 away from the base substrate 10.

The low-reflection film 40 is disposed in the non-light-emitting region FA. The low-reflection film 40 may include a plurality of metal layers 413 and a plurality of inorganic layers 424, and the plurality of metal layers 413 and the plurality of inorganic layers 424 are alternately stacked in sequence. A refractive index of the metal layer 413 is greater than that of the inorganic layer 424.

In some examples, as shown in FIG. 6, the low-reflection film 40 includes a first metal layer 41, a first inorganic layer 42, a second metal layer 43, and a second inorganic layer 44. The first inorganic layer 42 is located on a side of the first metal layer 41, and a refractive index of the first inorganic layer 42 is less than a refractive index of the first metal layer 41. The second metal layer 43 is located on a side of the first inorganic layer 42 away from the first metal layer 41, and a refractive index of the second metal layer 43 is greater than the refractive index of the first inorganic layer 42. The second inorganic layer 44 is located on a side of the second metal layer 43 away from the first inorganic layer 42, and a refractive index of the second inorganic layer 44 is less than the refractive index of the second metal layer 43.

For example, materials of the first metal layer 41 and the second metal layer 43 may both include molybdenum metal. For example, the refractive indexes of the first metal layer 41 and the second metal layer 43 may both be 2.3.

For example, materials of the first inorganic layer 42 and the second inorganic layer 44 may both include silicon nitride. For example, refractive indexes of the first inorganic layer 42 and the second inorganic layer 44 may both be 2.

As shown in FIG. 15, forming the low-reflection film 40 in step S400 may include step 451 and step 452.

In step 451, a first low-reflection base film is formed by sequentially forming a whole-layer first metal layer, a whole-layer first inorganic layer, a whole-layer second metal layer, and a whole-layer second inorganic layer that are stacked on the side of the light-emitting units 30 away from the base substrate 10.

For example, step 451 may include: forming the whole-layer first metal layer on the side of the light-emitting units 30 away from the base substrate 10 by using an evaporation process or a deposition process; forming the whole-layer first inorganic layer on a side of the whole-layer first metal layer away from the base substrate 10 by using a deposition process; forming the whole-layer second metal layer on a side of the whole-layer first inorganic layer away from the whole-layer first metal layer by using an evaporation process or a deposition process; and then, forming the whole-layer second inorganic layer on a side of the whole-layer second metal layer away from the whole-layer first inorganic layer by using a deposition process. The whole-layer first metal layer, the whole-layer first inorganic layer, the whole-layer second metal layer, and the whole-layer second inorganic layer that are stacked in sequence together form the first low-reflection base film.

In step 452, a portion of the first low-reflection base film located in the light-emitting regions EA is removed by using a dry etching process, where a portion of the first low-reflection base film located in the non-light-emitting region FA is retained as the low-reflection film 40 including the first metal layer 41, the first inorganic layer 42, the second metal layer 43 and the second inorganic layer 44.

In this way, refractive indexes of the first metal layer 41, the first inorganic layer 42, the second metal layer 43 and the second inorganic layer 44 shows a high-low-high-low pattern, and the incident light entering the low-reflection film 40 may be refracted or totally reflected at an interface between adjacent layers in the second inorganic layer 44, the second metal layer 43, the first inorganic layer 42 and the first metal layer 41. Therefore, the incident light entering the low-reflection film 40 may undergo multiple refractions or total reflections in the low-reflection film 40. As a result, the energy of the incident light may be consumed during the multiple refractions or total reflections, thereby increasing the amount of incident light absorbed and blocked by the low-reflection film 40, reducing the reflectivity of the low-reflection film 40 to the incident light, and improving the light-shielding effect of the low-reflection film 40. In addition, coherent light may be generated during the multiple refractions or total reflection, and destructive interference is likely to occur between two columns of coherent light at the peak and the trough, which may further increase the amount of incident light absorbed and blocked by the low-reflection film 40, further reduce the reflectivity of the low-reflection film 40 to the incident light, and further improve the light-shielding effect of the low-reflection film 40.

For example, as shown in FIG. 6, in the direction perpendicular to the first metal layer 41, the dimension L of the low-reflection film 40 is greater than or equal to 1800 Å and less than or equal to 2500 Å. For example, L may be 1800 Å, 1850 Å, 1876.5 Å, 1895 Å, 1900 Å, 1950 Å, 2000 Å, 2050 Å, 2100 Å, 2200 Å, 2350 Å, 2400 Å, 2450 Å, or 2500 Å.

For example, forming the whole-layer first metal layer, the whole-layer first inorganic layer, the whole-layer second metal layer, and the whole-layer second inorganic layer that are stacked in step 451 may include: forming the whole-layer first metal layer with a thickness of 1000 Å by using an evaporation process or a deposition process; forming the whole-layer first inorganic layer with a thickness of 376 Å on the side of the whole-layer first metal layer away from the base substrate 10 by using a deposition process; forming the whole-layer second metal layer with a thickness of 76.5 Å on the side of the whole-layer first inorganic layer away from the whole-layer first metal layer by using an evaporation process or a deposition process; and then, forming the whole-layer second inorganic layer with a thickness of 424 Å on the side of the whole-layer second metal layer away from the whole-layer first inorganic layer by using a deposition process.

In some examples, the low-reflection film 40 can include N metal layers 413 and a plurality of inorganic layers 424, and the N metal layers 413 and the plurality of inorganic layers 424 are alternately stacked in sequence. Here, N is a positive integer greater than or equal to three. For example, N is three, four, five or six.

Step 451 may include: forming a first low-reflection base film by alternately forming N whole-layer metal layers and a plurality of whole-layer inorganic layers stacked in sequence on the side of the light-emitting units 30 away from the base substrate 10. For example, in step 451, a deposition process may be used to alternately form the N whole-layer metal layers and a plurality of whole-layer inorganic layers. Then, in step 452, the low-reflection film 40 including the N metal layers 413 and the plurality of inorganic layers 424 is formed.

In this way, the incident light entering the low-reflection film 40 may be refracted or totally reflected at an interface between adjacent layers in the N metal layers 413 and the plurality of inorganic layers 424, and thus the incident light entering the low-reflection film 40 may undergo more refractions or total reflections in the low-reflection film 40. As a result, the low-reflection film 40 may consume more energy of the incident light, and destructive interference is more likely to occur during multiple refractions or total reflections, which may greatly increase the amount of incident light absorbed and blocked by the low-reflection film 40, reduce the reflectivity of the low-reflection film 40 to the incident light, and thereby greatly improve the light-shielding effect of the low-reflection film 40.

In some embodiments, as shown in FIGS. 7 and 8, the display substrate 100 may be a double-sided-emission display substrate 100, and the low-reflection film(s) 40 may be formed on side(s) of the plurality of metal wires 20 close to the at least one display side of the double-sided-emission display substrate 100.

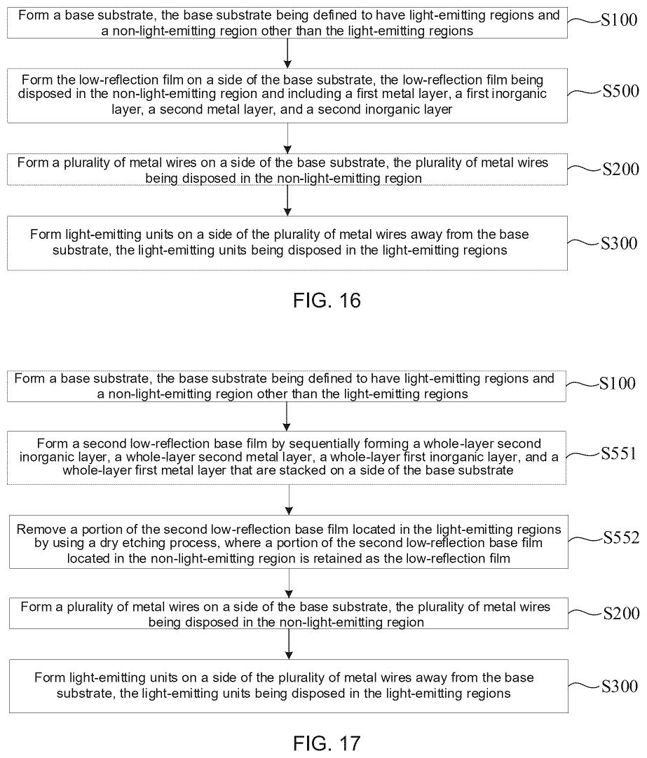

In some examples, as shown in FIG. 7, the low-reflection film 40 is formed on a side of the plurality of metal wires 20 close to one display side of the double-sided-emission display substrate 100. As shown in FIG. 16, the manufacturing method for the display substrate 100 may further include step S500. In step S500, before step S200, the low-reflection film 40 is formed on the side of the base substrate 10.

For example, as shown in FIG. 17, forming the low-reflection film 40 in step S500 may include step 551 and step 552.

In step 551, a second low-reflection base film is formed by sequentially forming a whole-layer second inorganic layer, a whole-layer second metal layer, a whole-layer first inorganic layer, and a whole-layer first metal layer that are stacked on the side of the base substrate 10. For example, step 551 may include: forming the whole-layer second inorganic layer on the side of the base substrate 10 by using a deposition process; forming the whole-layer second metal layer on a side of the whole-layer second inorganic layer away from the base substrate 10 by using an evaporation process or a deposition process; forming the whole-layer first inorganic layer on a side of the whole-layer second metal layer away from the whole-layer second inorganic layer by using a deposition process; and then, forming the whole-layer first metal layer on a side of the whole-layer first inorganic layer away from the whole-layer second metal layer by using an evaporation process or a deposition process. The whole-layer second inorganic layer, the whole-layer second metal layer, the whole-layer first inorganic layer, and the whole-layer first metal layer that are stacked in sequence together form the second low-reflection base film.

In step 552, a portion of the second low-reflection base film located in the light-emitting regions EA is removed by using a dry etching process, where a portion of the second low-reflection base film located in the non-light-emitting region FA is retained as the low-reflection film 40 including the second inorganic layer 44, the second metal layer 43, the first inorganic layer 42, and the first metal layer 41.

The structure and material properties of the low-reflection film 40 have been described in detail above, which will not be repeated here.

The low-reflection film 40 may block and absorb the incident light that would otherwise direct from one display side to the metal wires 20, so that less incident light may be reflected from the metal wires 20, thereby reducing the reflectivity of the incident light directing from the one display side to the metal wires 20 in the double-sided-emission display substrate 100, and improving the overall black display effect of the one display side of the double-sided-emission display substrate 100.

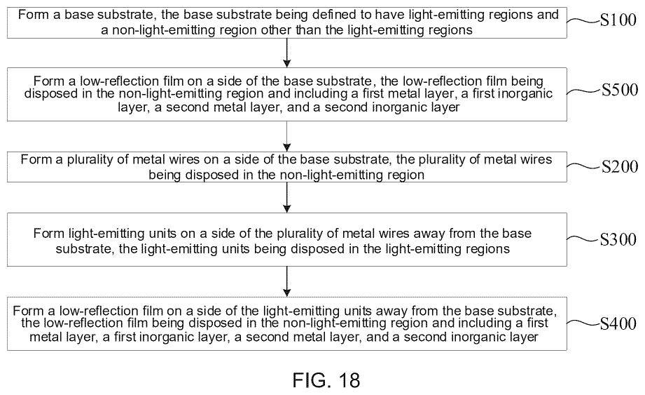

In some examples, as shown in FIG. 8, low-reflection films 40 are formed on both sides of the plurality of metal wires 20 close to two display sides of the double-sided-emission display substrate 100. As shown in FIG. 18, the manufacturing method for the double-sided-emission display substrate 100 may include step S100, step S500, step S200, step S300, and step S400 that are performed in sequence.

The low-reflection films 40 may block and absorb the incident light that would otherwise direct from the two display sides to the metal wires 20, so that less incident light may be reflected from the metal wires 20, thereby reducing the reflectivity of the incident light directing from the two display sides to the metal wires 20 in the double-sided-emission display substrate 100, and improving the overall black display effect of the double-sided-emission display substrate 100.

In summary, in the display substrate 100 manufactured by the above-mentioned manufacturing method, since the metal layer and the inorganic layer in the low-reflection film 40 have good thermal stability and high hardness, after the low-reflection film 40 is formed, the low-reflection film 40 will not be damaged during the laser etching process of metal leads located on the side of the display substrate 100, which may improve the manufacturing yield of the display substrate 100 and the display apparatus 1000. In addition, since the low-reflection film 40 has a good light-shielding effect, the low-reflection film 40 may absorb a large amount of incident light that would otherwise direct towards the metal wires 20, which may make the incident light reflected from the metal wires 20 relatively small, thereby reducing the reflectivity of the metal wires 20 in the display substrate 100 to the incident light, and improving the overall black display effect of the display substrate 100 and the display apparatus 1000. Moreover, since the stability and uniformity of the light-shielding effect of the low-reflection film 40 is relatively high, the fluctuation range of the reflectivity of the metal wires 20 in the display substrate 100 to the incident light is relatively small, which further improves the overall black display effect of the display substrate 100 and the display apparatus 1000.

The foregoing descriptions are merely specific implementations of the present disclosure, but the protection scope of the present disclosure is not limited thereto. Any variations or substitutions that those skilled in the art could conceive of within the technical scope of the present disclosure shall fall within the protection scope of the present disclosure. Therefore, the protection scope of the present disclosure should be determined by the protection scope of the claims.

What is claimed is:

1. A low-reflection film, comprising:
a first metal layer;
a first inorganic layer located on a side of the first metal layer, wherein a refractive index of the first inorganic layer is less than a refractive index of the first metal layer;
a second metal layer located on a side of the first inorganic layer away from the first metal layer, wherein a refractive index of the second metal layer is greater than the refractive index of the first inorganic layer; and
a second inorganic layer located on a side of the second metal layer away from the first inorganic layer, wherein a refractive index of the second inorganic layer is less than the refractive index of the second metal layer.

2. The low-reflection film according to claim 1, wherein in a direction perpendicular to the first metal layer, a dimension of the first metal layer is greater than a dimension of the first inorganic layer; and/or
in the direction perpendicular to the first metal layer, the dimension of the first metal layer is greater than a dimension of the second metal layer; and/or
in the direction perpendicular to the first metal layer, the dimension of the first metal layer is greater than a dimension of the second inorganic layer.

3. The low-reflection film according to claim 1, wherein in a direction perpendicular to the first metal layer, a ratio of a dimension of the first metal layer to a dimension of the first inorganic layer is greater than or equal to 2.5 and less than or equal to 3.5; and/or
in the direction perpendicular to the first metal layer, a ratio of the dimension of the first metal layer to a dimension of the second metal layer is greater than or equal to 11.5 and less than or equal to 17.5; and/or
in the direction perpendicular to the first metal layer, a ratio of the dimension of the first metal layer to a dimension of the second inorganic layer is greater than or equal to 2 and less than or equal to 3.

4. The low-reflection film according to claim 1, wherein in a direction perpendicular to the first metal layer, a dimension of the first inorganic layer is greater than a dimension of the second metal layer; and/or
in the direction perpendicular to the first metal layer, a dimension of the second inorganic layer is greater than the dimension of the second metal layer.

5. The low-reflection film according to claim 1, wherein in a direction perpendicular to the first metal layer, a ratio of a dimension of the first inorganic layer to a dimension of the second metal layer is greater than or equal to 4 and less than or equal to 6.5; and/or
in the direction perpendicular to the first metal layer, a ratio of a dimension of the second inorganic layer to the dimension of the second metal layer is greater than or equal to 4.5 and less than or equal to 7.

6. The low-reflection film according to claim 1, wherein in a direction perpendicular to the first metal layer, a dimension of the low-reflection film is greater than or equal to 1800 Å and less than or equal to 2500 Å.

7. The low-reflection film according to claim 1, wherein the low-reflection film comprises N metal layers and a plurality of inorganic layers, and the N metal layers have refractive indexes greater than refractive indexes of the plurality of inorganic layers; and the N metal layers and the plurality of inorganic layers are alternately stacked in sequence, wherein N is a positive integer greater than or equal to three.

8. A display substrate, comprising at least one display side, wherein the display substrate further comprises:
a base substrate, wherein the base substrate is defined to have light-emitting regions and a non-light-emitting region other than the light-emitting regions;
a plurality of metal wires located on a side of the base substrate and disposed in the non-light-emitting region;
light-emitting units located on a side of the plurality of metal wires away from the base substrate and disposed in the light-emitting regions; and
at least one low-reflection film according to claim 1, wherein the at least one low-reflection film is located on at least one side of the plurality of metal wires close to the at least one display side and is disposed in the non-light-emitting region.

9. The display substrate according to claim 8, wherein the display substrate is a top-emission display substrate; and the low-reflection film is located on a side of the light-emitting units away from the base substrate.

10. The display substrate according to claim 8, wherein the display substrate is a double-sided-emission display substrate; and the at least one low-reflection film includes:
a first low-reflection film located between the base substrate and the plurality of metal wires; and/or
a second low-reflection film located on a side of the light-emitting units away from the base substrate.

11. A manufacturing method for a display substrate, the method comprising:
forming a base substrate, wherein the base substrate is defined to have light-emitting regions and a non-light-emitting region other than the light-emitting regions;
forming a plurality of metal wires on a side of the base substrate, wherein the plurality of metal wires are disposed in the non-light-emitting region; and
forming light-emitting units on a side of the plurality of metal wires away from the base substrate, wherein the light-emitting units are disposed in the light-emitting regions, wherein
the method further comprises:
after forming the light-emitting units, forming a low-reflection film on a side of the light-emitting units away from the base substrate; and/or before forming the light-emitting units, forming a low-reflection film on the side of the base substrate, wherein
the low-reflection film is disposed in the non-light-emitting region; the low-reflection film includes a first metal layer, a first inorganic layer, a second metal layer and a second inorganic layer; the first inorganic layer is located on a side of the first metal layer, and a refractive index of the first inorganic layer is less than a refractive index of the first metal layer; the second metal layer is located on a side of the first inorganic layer away from the first metal layer, and a refractive index of the second metal layer is greater than the refractive index of the first inorganic layer; the second inorganic layer is located on a side of the second metal layer away from the first inorganic layer, and a refractive index of the second inorganic layer is less than the refractive index of the second metal layer.

12. The manufacturing method for the display substrate according to claim 11, wherein forming the low-reflection film on the side of the light-emitting units away from the base substrate, includes:
forming a first low-reflection base film by sequentially forming a whole-layer first metal layer, a whole-layer first inorganic layer, a whole-layer second metal layer, and a whole-layer second inorganic layer that are stacked on the side of the light-emitting units away from the base substrate; and
removing a portion of the first low-reflection base film located in the light-emitting regions by using a dry etching process, wherein a portion of the first low-reflection base film located in the non-light-emitting region is retained as the low-reflection film.

13. A display apparatus, comprising:
a circuit board; and
the display substrate according to claim 8, wherein the display substrate is located on a side of the circuit board, and is coupled to the circuit board.

14. The low-reflection film according to claim 7, wherein a material of a metal layer in the N metal layers includes at least one of molybdenum, copper, aluminum, silver, and an alloy thereof.

15. The low-reflection film according to claim 7, wherein a material of an inorganic layer in the plurality of inorganic layers includes silicon nitride, silicon dioxide, or silicon trioxide.

16. The display substrate according to claim 8, wherein the display substrate is a bottom-emission display substrate; and the low-reflection film is located between the base substrate and the plurality of metal wires.

17. The manufacturing method for the display substrate according to claim 11, wherein forming the low-reflection film on the side of the base substrate, includes:
forming a second low-reflection base film by sequentially forming a whole-layer second inorganic layer, a whole-layer second metal layer, a whole-layer first inorganic layer, and a whole-layer first metal layer that are stacked on the side of the base substrate; and
removing a portion of the second low-reflection base film located in the light-emitting regions by using a dry etching process, wherein a portion of the second low-reflection base film located in the non-light-emitting region is retained as the low-reflection film.
